(19) United States
(12) Patent Application Publication
(10) Pub. No.: US 2023/0356452 A1
(43) Pub. Date: Nov. 9, 2023

(54) PRODUCTION OF STRUCTURED SURFACES

(71) Applicant: FORSCHUNGSZENTRUM JUELICH GMBH, Juelich (DE)

(72) Inventors: Jens ELGETI, Juelich (DE); Gerhard GOMPPER, Juelich (DE); Stephan FOERSTER, Juelich (DE); Lucas DE QUEIROZ DA COSTA CAMPOS, Koeln (DE)

(21) Appl. No.: 18/004,905

(22) PCT Filed: Jun. 11, 2021
(86) PCT No.: PCT/EP2021/065763

§ 371 Date: Jan. 10, 2023

(30) Foreign Application Priority Data
Jul. 14, 2020 (DE) 102020118555.3

(51) Int. Cl. B29C 53/04; B29C 55/02; B29C 59/14; B29C 59/16

(52) U.S. Cl. CPC B29C 53/04; B29C 55/02; B29C 59/14; B29C 59/16

(57) ABSTRACT

Three-dimensionally structured surfaces starting from an elastic material by stretching, selective treatment of different surface regions and relaxation.

The present invention relates to the targeted production of surface structures, in particular complex surface structures, and in particular down to the micro- and nanometer range and likewise three-dimensionally structured surfaces starting from an elastic material by stretching, selective treatment of different surface areas and relaxation.

Surface technologies play an important role in almost all manufacturing processes, from the metalworking industry to the semiconductor industry to biomedicine, from mechanical engineering, plant engineering and toolmaking to optics, microelectronics, medical technology, the automotive industry and plastics processing to building services engineering and architecture. The aim of surface technologies is to change surface properties such as corrosion resistance, wettability, biocompatibility, flow properties, etc., even independently of the actual material or material of a component. In most cases, new surface properties lead to a better quality of products or enable components and products to be used or utilized in the first place. Such functional surfaces are created, for example, by microstructuring. A wide range of manufacturing processes are available for creating structured surfaces, such as simple folding techniques, X-ray lithography, 3D printing, laser ablation, various coating processes and classic lithographic techniques mainly the laser-based microstructuring processes for the high-precision structuring of a wide variety of materials are to be mentioned. All these processes have their advantages, but also disadvantages. Complex functional microstructures are gaining importance in many applications, among other things because of increasing miniaturization.

X-ray lithography allows fabrication of very fine structures, but is very expensive and only possible on a relatively small scale. In addition, structures with overhangs are very laborious. 3D printing allows only relatively coarse structures and is not particularly fast in terms of throughput. With laser ablation similarly fine surface structures can be made. However, this method is relatively expensive and cannot produce structures with overhangs.

An up to now relatively little-used method for ultra-precise surface structuring is based on regular fold formation when a pre-stressed elastic material (usually polymers) contracts with a subsequently applied stiffer surface layer. Since during relaxation the surface layer can contract less than the substrate, a very regular fold pattern of microscopic folds is formed. Although this process is relatively cost-efficient and can lead to customized surface structures, it has been little used to date. This is mainly due to the previous limitations of the possible variety of structures. Examples for the prior art are US 2012/0305646 A1 and U.S. Pat. No. 10,472,276 B2.

It is the object of the present invention to provide possibilities for the structuring of surfaces, in particular in the micrometer range.

Furthermore, it was the object of the present invention to find possibilities how surface structures can be optimized.

In that the possibilities should no longer exhibit the problems of the prior art.

Further objects unfold themselves to the person skilled in the art when considering the following description and the claims.

These and further objects, which become apparent to the person skilled in the art upon consideration of the present description, are solved by the subject matter illustrated in the independent claims.

Particularly advantageous and preferred subject matter will be apparent from the dependent claims and the following description.

Within the scope of the present invention, a novel process for functional surface coating is presented, which is characterized by a plurality of feasible surface structures and is of interest for a wide range of industrial applications.

An essential aspect of the present invention is to spatially vary in a targeted manner the properties and condition of a surface layer applied to a preferably elastic substrate, such as its thickness or elasticity.

By controlled inhomogeneity of these parameters, a very wide range of complex structures can be generated in one step.

The resulting surface-structured material can be used directly, but it can also be taken as a “mold” for various other materials, e.g. epoxy resins, thermoplastics or concrete, so that the process is available for a wide range of materials.

Consequently, a subject matter of the present invention is a process for the production of three-dimensionally structured surfaces, in which, in a first step, an elastic material is provided. Subsequently, this material is stretched by a predetermined value and the stretched state is initially maintained. Thereafter, a two-dimensional pattern is then applied or transferred to or introduced into the surface of the elastic material in the stretched state. Then, after the stretching is released, the elastic material relaxes and, due to the pattern transferred to or introduced into the surface, folds itself in a certain pattern.

This results in a three-dimensionally structured surface, the folding of which corresponds directly to the pattern transferred to or introduced into the elastic material in the stretched state.

This three-dimensionally structured surface produced in this way may in itself represent the desired product. However, it is just as well possible to mold this surface, i.e. to apply other materials to the structured surface and consequently then to perform an inverse molding, i.e. to obtain a three-dimensionally structured surface in the second material which represents a direct inversion of the surface of the elastic material.

Within the scope of the present invention, in principle, all elastic materials can be used for this process which can be structured in some way, or to which a two-dimensional pattern can be applied in some way, such that the surface properties and condition/elasticity of the pattern structure then differs from that of the non-patterned surface areas.

In the context of the present invention, in principle, all elastic materials can be used. For example, materials having a tensile modulus of 10 Pa, such as very soft elastomers, to those having tensile moduli of up to 1000 GPa, such as very hard metal and glass, can be used. It is known to the person skilled in the art that these are extreme examples with which the process according to the invention may only function to a limited extent and only minor surface structurings are obtained.

In this respect, it is preferred according to the invention to use as elastic materials those whose tensile moduli are in the range from about 100 kPa to 10 MPa; exemplary for such materials would be polydimethylsiloxanes (PDMS).

Regardless of the selection option via tensile moduli, examples of elastic materials that can be used in the context of the present invention are rubber or elastomers, particularly elastomers based on silicone, such as polydimethylsiloxanes (PDMS), polyurethane, polybutadiene, polyisoprene, and copolymers such as SBR, NBR, EPM, EVA.

In this process, the transfer of the two-dimensional pattern to or the introduction into the surface of the elastic material, which is in the stretched state, can in principle be carried out by any conceivable means.

For example, it is conceivable to present a surface of rubber, stretch it, and then apply a second material to this surface. This second material would have a certain structure, which then leads to a defined folding of the surface and thus to a three-dimensionally structured surface when the rubber relaxes. Such a material to be applied to the rubber could be, for example, in a simple embodiment, aluminum foil with holes therein. Furthermore, when rubber is provided, a pattern could be painted or printed on the surface with an adhesive. Provided that the adhesive then hardens and the stretching is released, the rubber relaxes and folds according to the structure applied to it by the adhesive in a precisely defined three-dimensionally structured surface. It is advantageous for this procedure if the adhesive in its cured form is harder than the surrounding rubber.

Furthermore, it is conceivable to provide an elastic material, stretch it and then burn or melt structures into the surface, for example by means of a laser, i.e. to remove the surface here at precisely desired and defined points (in contrast to irradiation by laser light in the sense of exposure). This procedure can be carried out in a similar way to direct laser writing, whereby the focus of the laser light is concentrated on certain desired areas in such a way that with that the elastic material can be liquefied or vaporized at this location. Upon relaxation, a three-dimensional surface structure corresponding to the burned or removed pattern is then formed.

In preferred embodiments of the present invention, the introduction of the two-dimensional pattern into the surface of the elastic material in the stretched state is carried out by first covering or protecting specific surface areas of the material by covering or as well by applying a protective substance, and then allowing oxygen plasma to act on the surface. In this case, the oxygen plasma would then be able to reach the surface areas that are not covered or not protected by a protective substance and change the surface there by chemical reactions. After the oxygen plasma has then been allowed to act on the surface for a certain predetermined duration, the oxygen plasma supply is stopped, and then the covering or protective substance (protective material) is then removed from the surface. Provided that the stretching is then removed, the material relaxes and forms a defined three-dimensionally structured surface, depending on the surface areas changed by the oxygen plasma in relation to the surface areas not changed.

The protective substance (protective material) can be, for example, a protective lacquer, which is applied to the stretched surface, for example, by means of pad printing or other printing processes, such as via an inkjet printer. The removal of the protective coating can be done, for example, by rinsing with suitable solvents. Both appropriate coatings as well as solvents are known to the person skilled in the art. In other embodiments of the present invention, a reactive gas is used instead of oxygen plasma. However, the procedure otherwise remains the same. Examples of reactive gases are ozone, chlorine or hydrogen chloride.

Another preferred embodiment is a method for producing three-dimensionally structured surfaces comprising the following steps or consisting thereof:
Providing an elastic material,
stretching the elastic material by a predetermined value and maintaining the stretched state,
treating the surface of the stretched material, which is covered in parts by application of a protective substance, by means of oxygen plasma or a reactive gas, preferably selected from the group consisting of ozone, chlorine and hydrogen chloride, for a specific duration,
cancelling the stretched state,
optionally molding of the three-dimensionally structured surface thus produced.

In preferred embodiments of the present invention, the protected areas, the protective materials, the plasma or reactive gas and the duration of exposure and/or the degree of stretching of the elastic material are set depending on the elastic material used.

In another embodiment, the introduction of the two-dimensional pattern onto the surface of the elastic material in the stretched state is performed by irradiation using electromagnetic irradiation. For this purpose, an irradiation mask is first arranged between the radiation source and the elastic material.

This irradiation mask can be arranged anywhere on the radiation path between the radiation source and the surface of the material, but can also be arranged in direct contact laid on the surface. Depending on the exact pattern desired, the person skilled in the art may select the most appropriate distance between the surface, radiation source and irradiation mask. In this context, the person skilled in the art will then take into account—depending on the radiation used—the extent to which the irradiation mask leads to diffraction effects or not, or the extent to which these are desired.

After the irradiation mask has been arranged, irradiation then takes place by means of electromagnetic radiation with a radiation duration and radiation intensity required for the desired surface structure.

After completion of the irradiation, the irradiation mask is then removed and the stretched state is cancelled. During the subsequent relaxation of the elastic material, folding to the desired three-dimensionally structured surface occurs depending on the irradiation pattern.

In this embodiment, the irradiation mask can be either a reusable rigid mask, for example a metal or plastic stencil, or a protective coating which can be applied to the stretched surface, for example by means of pad printing or other printing processes, such as via an inkjet printer. In the latter case, the removal of the protective mask would then mean the removal of the protective coating, for example by rinsing with suitable solvents. Both appropriate coatings as well as solvents are known to the person skilled in the art.

Another preferred embodiment is a method for producing three-dimensionally structured surfaces comprising the following steps or consisting thereof:
Provision of an elastic material,
stretching the elastic material by a predetermined value and maintaining the stretched state,
irradiating the elastic material in the stretched state by means of electromagnetic radiation using an irradiation mask for a specific duration and with a predetermined radiation intensity,
cancelling the stretched state,
optionally molding of the three-dimensionally structured surface thus produced.

In connection with the transfer of the two-dimensional pattern to or the introduction of the two-dimensional pattern into the stretched surface of the elastic material, it is clear to the person skilled in the art that this two-dimensionality is to be seen relatively and not in the mathematical sense with height 0. For, regardless of the process by which this pattern is ultimately transferred or introduced, the surface of the elastic material is changed in some way. Since the elastic material is a physically existing material, the surface always naturally has a certain depth in addition to length and width, as does the pattern transferred to or introduced into this surface. For example, in the case of an irradiation by means of electromagnetic radiation, this electromagnetic radiation will always also have a certain depth of penetration into the material, so that the surface change takes place to a certain depth of the surface (for example, a cross-linking stimulated by UV rays). Likewise, of course, this applies to painting or printing the surface with, for example, adhesive. However, it is essential and to be understood by this in the sense of the present invention that this two-dimensional structure designated in this way or the two-dimensional surface pattern has orders of magnitude less surface structuring than the three-dimensional surface structure subsequently obtained by folding.

In further embodiments of the present invention, instead of irradiation or treatment with plasma or reactive gases, a pattern can also occur by targeted, precise application of chemical compounds that react with the surface molecules of the substrate, to the surface.

In this case, the application must be done with very fine nozzles to enable the fine structuring desired in the context of the present invention. In embodiments, the application may be carried out by means of printers based on “ink jet technology”, i.e. printers are used that have very fine application nozzles, with nozzle openings that can produce droplets of less than 100 picoliters, preferably less than 50 picoliters, more preferably less than 20 picoliters. In these, a chemical or mixture of chemicals that react with the molecules of the substrate surface can then be used in the print cartridges instead of the inks. After this solution is “printed” onto the substrate surface, the molecules react with each other and the sprayed or printed pattern results from the surface molecules converted by chemical reaction. In simple variants, this can be done in a manner known in principle in polymer chemistry in that a substance is made to react with a suitable hardener substance or crosslinker substance. The substance to be printed/applied can either be used pure or as a mixture with co-crosslinkers or dissolved in solvents; this is known to the person skilled in the art and therefore does not need to be discussed in detail here.

With this procedure, virtually any pattern can be applied, which can, for example, be created on the computer using simple graphics programs.

This procedure is therefore highly flexible.

The only thing that needs to be taken into account is that the substrate itself must be sufficiently stable and, above all, elastically stretchable so that it can contract again after printing, reaction and cancellation of the stretching and form the desired surface structure.

Particular examples of liquids that can be used in the context of this approach would be, in the case of polydimethylsiloxane being used as substrate, the crosslinkers known for this purpose; preferred examples are 4,5′-bis(diethylamino)benzophenone, thioxanthene-9-one or 2,2-dimethoxy-2-phenylacetophenone.

PDMS is often offered pre-mixed together with the appropriate crosslinker, a commercially available example being Sylgard® 184. Such pre-prepared mixtures can be directly printed and cured using this variant of the present invention.

It is also possible to print another layer of PDMS onto the (PDMS) substrate and then cure it (thermally or by radiation), whereby the printed areas are additionally reinforced by, possibly more highly crosslinked, PDMS.

Depending on the need, the PDMS or the curing agents are solved in suitable solvents for that; preferred examples of such solvents are methyl isobutyl ketone, toluene, isobutyl acetate and octyl acetate (mainly for PDMS) and acetonitrile, (mainly for the crosslinkers).

In embodiments of the present invention, the stretched elastic material is only one layer of a multilayer workpiece. In this regard, this multilayered workpiece may consist of at least two layers, or at least three or appropriately more layers. It is possible that the different layers consist of different materials, or also that the different layers consist of the same materials arranged one above the other. The latter can be useful, for example, if an anisotropic material is used whose properties exhibit predominant directions. In such a case, one could superimpose this material in layers rotated against each other, for example arranged rotated by 90°. In embodiments, the multilayer material may also be obtained after structuring the uppermost layer by applying this layer to the remaining layer(s).

In preferred embodiments of the present invention, the irradiation mask, the duration of the irradiation, the radiation intensity and the exact form of the electromagnetic radiation and/or the degree of stretching of the elastic material are determined depending on the elastic material used.

This determination can be made on the basis of experimental data and correspondingly created databases or calculated on the basis of computer simulations.

Accordingly, the determination of the exact shape and structure of the irradiation mask, the duration of the irradiation, the radiation intensity and/or the degree of stretching, or analogously the type and shape of the protective materials, the protected regions and the plasma or reactive gas, is carried out experimentally in embodiments of the present invention, experimentally iteratively in other embodiments, iteratively by means of machine learning in other embodiments, and by means of computer simulations in further embodiments. Further, it is possible to combine these selection methods. For example, a part of the parameters, such as the shape of the irradiation mask, may have been determined experimentally, and another part, e.g. the radiation intensity, may have been determined experimentally iteratively, whereas the degree of stretching may originate from machine learning or computer simulations.

The exact selection and application of these methods is thereby based on the specifications for the particular project desired.

In embodiments of the present invention, the experimental iterative determination may thereby be performed as follows:

First, a desired three-dimensional surface structure is specified, which shall be achieved for a defined elastic material.

Next, a two-dimensional surface pattern is proposed which, after irradiation through an irradiation mask to be proposed, or treatment by plasma or reactive gas of unprotected surface areas, should fold into a structure as similar as possible to that of the specification.

Likewise, parameters are then proposed for the duration of irradiation, radiation intensity, or duration and intensity of plasma/gas treatment, and/or the degree of stretching.

With these proposed parameters and surface patterns, a method is then performed as described above.

Next, the product obtained by this method is then compared to the obtained three-dimensional surface structure with respect to the specified surface structure. Provided that the obtained surface structure has a sufficient match with the specified structure, the obtained product is output.

This output ultimately means that the obtained product is suitable as a final product and a can be easily supplied to its use or further processing. Provided that the method is carried out in a closed system, for this purpose the method can also be stopped and a notification to the user can be made, for example, by visual or acoustic signal or by e-mail or by other usual means.

The proposed structure or parameters for the irradiation, the shape of the irradiation mask and the proposed pattern as well as the obtained three-dimensional surface structure can then optionally be stored; analogously, the type and shape of the protective materials, the protected areas and the plasma or reactive gas can be stored. In preferred embodiments, these data are stored in the form of a parameter set which is given a precise, unique designation and, in conjunction with further such parameter sets, can form a corresponding manufacturing database.

If, after manufacturing the three-dimensional surface structure, it is found that the match between the actually obtained three-dimensional surface structure and the specified target surface structure is not sufficient, the just described steps of proposing a two-dimensional surface pattern, an irradiation mask and parameters for the irradiation, or type and form of the protective materials, protected areas and the plasma or reactive gas, as well as the carrying out of the method as described above and the comparison of the obtained structures are repeated. For this purpose, one or more of the mentioned parameters and propositions are changed. It is preferred to change only one parameter or proposition at a time in order to obtain reproducibility and a result that is as meaningful as possible and that can be traced back to a specific parameter or its change. The changes can be specified more or less arbitrarily by the experimenter, selected on the basis of previous experimental work, or with the help of algorithms, preferably those that operate in a neural network.

The results obtained in this way are also optionally stored again as just described. This repetition of steps is carried out until a sufficient match is obtained between the specified three-dimensional structure and the three-dimensional structure actually obtained.

By storing the data in the form of a database, it is achieved that a large amount of data is built up, with which it then becomes increasingly easy to make predictions as to which initial patterns, irradiation masks or irradiation parameters must be used in order to obtain a certain specified three-dimensional surface structure.

It is understood that this method described with respect to an irradiation of the surface is analogously applicable to the other methods of applying a pattern to the surfaces described above, in particular the treatment with oxygen plasma.

In further embodiments of the present invention, the iterative determination by means of machine learning may thereby be performed as follows: First, a desired three-dimensional surface structure is specified, which shall be achieved for a defined elastic material.

Next, a two-dimensional surface pattern is proposed, after irradiation through an irradiation mask, which is also to be proposed, or treatment by plasma or reactive gas of unprotected surface areas, should fold into a structure as similar as possible to that of the specification.

Likewise, parameters for the duration of irradiation, radiation intensity and/or degree of stretching are then proposed.

With these proposed parameters and surface patterns, calculations are then performed, using a simulation program. Preferably, this is a simulation program based on the finite element method.

The data used for the calculation for specified three-dimensional surface structure, proposed two-dimensional surface pattern, proposed irradiation mask, proposed irradiation parameters or proposed protected areas of the surface and duration and intensity of plasma/gas treatment, are passed as a learning data set to the algorithm and neural network, respectively.

Next, the result of a three-dimensional surface structure obtained from this calculation is then compared with the specified surface structure. If the calculated three-dimensional surface structure has a sufficient match with the specified structure, the obtained result is output. With this result and the associated parameters, a real, physical implementation and production of the desired product can then take place.

The said output can be carried out in the usual way. For example, as a display on a monitor, as a printout, or also as a direct transmission of the data, e.g. as control data, to a connected manufacturing unit. There may also be a notification to the user, for example, by visual or acoustic signal, or by e-mail, or in other usual ways.

The proposed/calculated structure or the proposed/calculated parameters for the irradiation, the shape of the irradiation mask and the proposed/calculated pattern, as well as the three-dimensional surface structure obtained as result of the calculation, can then optionally be stored; analogously, the type and form of the protective materials, the protected areas and the plasma or reactive gas can be stored.

In preferred embodiments, these data are stored in the form of a parameter set which is given a precise, unique designation and, in conjunction with further such parameter sets, can form a corresponding manufacturing database.

If, after calculation of the three-dimensional surface structure, it is found that the match between the calculated three-dimensional surface structure and the specified target surface structure is not sufficient, the just-described steps of proposing a two-dimensional surface pattern, an irradiation mask and parameters for the irradiation, or type and form of the protective materials, the protected areas and the plasma or reactive gas, as well as the calculation as described above and the comparison of the calculated and the specified structures are repeated, with the data of the learning data set being included in the calculation. For this purpose, one or more of the mentioned parameters and proposals are changed. It is preferred to change only one parameter or proposal at a time in order to obtain reproducibility and a result that is as meaningful as possible and can be traced back to a specific parameter or its change. The changes are preferably specified by the program/algorithm. In principle, however, it is also possible to have them specified by the experimenter. The results obtained in this way are also optionally stored again as just described.

This repetition of the steps takes place until a sufficient match between the specified three-dimensional structure and the calculated three-dimensional structure is reached. By storing the data in the form of a database, it is achieved that a large amount of data is built up, with which it then becomes increasingly easy to make predictions as to which initial patterns, irradiation masks or irradiation parameters, or type and form of the protective materials, the protected areas and the plasma or reactive gas, must be used in order to obtain a certain specified three-dimensional surface structure.

In the context of this machine-learning based embodiment, the first starting data set for the proposal of surface patterns, irradiation masks or irradiation parameters, or type and form of the protective materials, the protected areas and the plasma or reactive gas, can either be specified by a computer program or manually entered by the user, for example based on previous experimental results.

It is understood that this method described with regard to irradiation of the surface is also analogously applicable to the other methods of applying a pattern to the surfaces described above, in particular the treatment with oxygen plasma.

In further embodiments of the present invention, it is also possible to follow the reverse path. Accordingly, it is possible to specify the desired three-dimensional surface structure, the irradiation mask, the duration of the irradiation, the irradiation intensity, or type and form of the protective materials, the protected areas and the plasma or reactive gas, and/or the degree of stretching, and then, on the basis of this, to determine which material parameters an elastic material to be used must have and/or which elastic material can be used.

This determination is of course the more accurate, the larger an existing data set is.

In preferred embodiments of the described iterative determination, both experimentally and by machine learning, the proposed two-dimensional surface pattern corresponds to at least one, preferably exactly one, defined exposure or irradiation mask.

In embodiments, the three-dimensional patterned surfaces resulting from the method of the present invention have hierarchical folds, overhangs, channels, microfluidic channels, particularly with smooth, rounded cross-sections, nubs, and/or combinations thereof.

In some embodiments, the resulting three-dimensional structured surface has microfluidic channels with smooth, rounded cross-sections.

Also subject matter of the present invention are workpieces having a three-dimensionally structured surface, wherein the surfaces have hierarchical folds, overhangs and/or microfluidic channels, with smooth, rounded cross-sections, in particular workpieces produced by any of the methods described above.

Equally subject matter of the present invention are workpieces having a three-dimensional textured surface structure, made according to a method of the present invention.

Accordingly, the present invention also includes corresponding workpieces, wherein these workpieces comprise at least two layers and the uppermost layer is formed by a correspondingly three-dimensionally structured surface.

Further subject matter of the present invention is a method for optimizing three-dimensionally structured surfaces by means of machine learning, wherein the machine learning after specification of a desired three-dimensional target surface structure comprises or consists of the following steps: First, a desired three-dimensional surface structure is specified, which shall be achieved for a defined elastic material.

Next, a two-dimensional surface pattern is proposed that, after irradiation through an irradiation mask that is also to be proposed, should fold into a structure as similar as possible to that of the specification.

Likewise, parameters are then proposed for the duration of irradiation, the radiation intensity, and/or the degree of stretching.

With these proposed parameters and surface patterns, calculations are then performed, using a simulation program. Preferably, this is a simulation program based on the finite element method. In embodiments of the present invention, the “Program for Determining the Folding of the Human Brain in the Course of Embryonic Development” (“Programm zur Bestimmung der Faltung des menschlichen Gehirns im Laufe der Embryonalentwicklung”) may be used for this purpose, with adaptation if necessary.

The data used for the calculation for specified three-dimensional surface structure, proposed two-dimensional surface pattern, proposed irradiation mask, proposed irradiation parameters are given as a learning data set to the algorithm and the neural network, respectively.

Next, the result of a three-dimensional surface pattern obtained from this calculation is then compared with the specified surface pattern. If the calculated three-dimensional surface structure has a sufficient match with the specified structure, the obtained result is output. With this result and the associated parameters, a real, physical implementation and production of the desired product can then take place. The said output can be carried out in the usual way. For example, as a display on a monitor, as a printout, or also as a direct transmission of the data, e.g. as control data, to a connected manufacturing unit. There may also be a notification to the user, for example, by visual or acoustic signal, or by e-mail, or in other usual ways.

The proposed/calculated structure or the proposed/calculated parameters for the irradiation, the shape of the irradiation mask and the proposed/calculated pattern as well as the three-dimensional surface structure obtained as the result of the calculation can then optionally be stored.

In preferred embodiments, these data are stored in the form of a parameter set which is given a precise, unique designation and, in conjunction with further such parameter sets, can form a corresponding manufacturing database.

If, after calculation of the three-dimensional surface structure, it is determined that the match between the calculated three-dimensional surface structure and the predetermined target surface structure is not sufficient, the just-described steps of proposing a two-dimensional surface pattern, an irradiation mask and parameters for the irradiation, as well as the calculation as described above and the comparison of the calculated and the specified structures are repeated, with the data of the learning data set being included in the calculation. For this purpose, one or more of the mentioned parameters and proposals are changed. It is preferred to change only one parameter or proposal at a time in order to obtain reproducibility and a result that is as meaningful as possible and can be traced back to a specific parameter or its change. The changes are preferably specified by the program/algorithm. In principle, however, it is also possible to have them specified by the experimenter. The results obtained in this way are also optionally stored again as just described.

This repetition of the steps takes place until a sufficient match between the specified three-dimensional structure and the calculated three-dimensional structure is reached. By storing the data in the form of a database, it is achieved that a large amount of data is built up, with which it then becomes increasingly easy to make predictions as to which initial patterns, irradiation masks or irradiation parameters must be used in order to obtain a certain specified three-dimensional surface structure.

It is understood that also this method described with regard to an irradiation of the surface is analogously applicable to the other methods of applying a pattern to the surfaces described above, in particular the treatment with oxygen plasma.

In the context of the present invention, a high edge sharpness of the pattern/patterning introduced into the surface is aimed at. This means that with the small size of the structures according to the invention, the individual structural elements of which, such as channels, are less than 1 mm in preferred embodiments direct incorporation of such structures into the surface by means of direct irradiation through plasma nozzles, in particular those with nozzle openings of 0.5 cm and more, is not possible, since this would lead to too low edge sharpness and inhomogeneous structures; in such an approach the individual pattern elements would, on the one hand, merge into one another and, on the other hand, due to the insufficiently sharp pattern edges, would not fold precisely enough when the tension is released, so that precise control of the patterns and consequently of the resulting folding would no longer be possible.

Preferred embodiments of the present invention are the methods according to the invention for producing structured surfaces with pattern sizes of less than 1 mm, preferred are pattern sizes between 100 nm and less than 1 mm.

In this regard, these sizes are the widths of the structures, the length of a respective structure may of course be greater. Accordingly, in the embodiment of the channel structures preferred in one embodiment of the present invention, channels are obtainable, for example, which have a width of 100 nm to less than 1 mm, preferably 100 nm to 0.5 mm, particularly preferably 1 μm to 100 μm or 50 μm to 500 μm or 300 μm to 500 μm, and which may have a length of several cm. The depth results thereby from the desired structure and, in some preferred embodiments, may be, for example, be at 50 μm to 0.5 μm.

In the comparisons made or to be made in the above-described methods as to whether the achieved or calculated three-dimensionally structured surface matches the specified three-dimensional surface structure (the target structure), it is checked whether the match is sufficient.

What is ultimately sufficient depends on various factors.

In one variant, tolerances are already specified in the target structure specification within which the result may deviate from the target structure. For example, for a microchannel of a width of 0.5 μm, a tolerance of ±0.001 μm may be acceptable in embodiments. In other embodiments, for a microchannel of a width of 50 μm, a tolerance of +5 μm may be acceptable.

In one variant, the result obtained is inspected by the user, who then decides whether the result is sufficient for the desired application. If, for example, the structure is not intended to serve a practical purpose but only to be aesthetically pleasing, a significant deviation may possibly also already be aesthetically pleasing and therefore acceptable.

In further variants, it is specified by the algorithm used or by the user what percentage deviation from the target value (for example, the target width of a channel) is sufficient.

Further ways of determining what constitutes a sufficient match are apparent to the person skilled in the art from his general knowledge and upon application.

Within the scope of the present invention, it is possible to produce three-dimensionally structured surfaces that have structures down to the nanometer range with the aid of the methods described.

With the aid of the present invention, it is possible to produce three-dimensionally structured surfaces that are precisely tailored to the desired particular field of application.

Due to the fact that the exact parameters can also be determined iteratively using machine learning in the context of the present invention, it is possible to create a large database in a relatively short time, with the aid of which upon request for a specific desired three-dimensionally structured target surface, the necessary parameters for its production can be provided.

In this case, it is also a significant advantage that by the computer simulations and machine learning, in addition to the pure time savings over experimental testing, important raw materials can be saved.

In embodiments of the present invention, an elastomer is stretched and then selectively cured (for example, cross-linked by UV light) in various areas, creating a surface pattern. When the stretching is then released, the elastomer contracts again. Due to the fact that there is a surface pattern of cured and uncured areas, the elastomer contracts unevenly and a folding caused by the structure of the cured and uncured areas occurs. In that the areas are selectively cured or not cured, it is possible to specifically influence and control the surface structure and the structure of the folding. In this way, defined “folding structures” can be produced.

Useable elastomers are, for example, those based on polydimethylsiloxane (PDMS). Although PDMS itself is difficult to cure or crosslink by UV radiation, there are modified PDMS on the market that are chemically modified by the incorporation of e.g. vinyl groups and/or to which other substances for crosslinking are admixed e.g. radical formers like benzophenone or peroxides. It is also possible to provide unmodified PDMS and to add radical formers, preferably benzophenone, to it before use according to the present invention.

Examples of commercially available PDMS (systems) that can be cured or crosslinked by UV radiation are Dow Corning WL-5000 or Sylgard® 184 PDMS Kit.

The exact dimensions of the surface structures result from the precise material properties of the elastic material used, the thickness of the material layer, the irradiation parameters (e.g. radiation intensity, radiation duration) and the irradiated areas or the employed irradiation masks or the conditions of the exposure to oxygen plasma or reactive gas, such as the exposure duration.

Within the scope of the present invention, it is possible to irradiate the most elastic materials used with radiation of different energies or wavelengths.

The exact selection of the radiation is made in coordination with the material to be irradiated. It is known to the person skilled in the art in this context that and how the radiation is to be selected depending on material properties. For example, there are a wide variety of crosslinking mechanisms, which differ in their respective energies required for activation.

In embodiments of the present invention, the radiation used may be in the range from infrared radiation to ultraviolet radiation.

In other variants, it is possible to use higher energies, for example X-rays, but this is often avoided for purely practical reasons (high energy requirements, safety aspects). In preferred variants of the present invention, UV radiation is used as the radiation; this is applicable to a great many crosslinking systems and can then be adapted in individual cases by precise selection of wavelength, radiation intensity and radiation duration.

The exact electromagnetic radiation used in the variants of pattern application by means of irradiation according to the invention unfolds to the person skilled in the art on the basis of customary considerations.

Depending on the material to be structured, radiation powers and intensities can be selected so as not to destroy the material or to achieve a specific change in the material.

As is known to the person skilled in the art, this also depends on the chemical composition/structure of the material used, whether it is, for example, a substance that upon excitation undergoes internal crosslinking, or whether it is a mixture of substances in which only a crosslinker needs to be activated (e.g. cleaved), whereby crosslinking reactions are then set in motion.

For purely practical reasons, the use of UV radiation is preferred in some embodiments.

In embodiments of the present invention, photo-crosslinking and plasma treatment are used to provide flat substrates of elastic polymers in uni- and biaxially stretched states with a surface layer of certain thickness and crosslink density. By the crosslinking density the modulus of elasticity can be set according to the specifications, for example from a simulation. The fold formation starts when the material relaxes into the unstretched state and can immediately be compared with the specifications or the predictions of the simulation.

In the embodiments of the present invention in which the structuring of the surface of the elastic material is carried out by irradiation, photo-crosslinking, treatment with reactive gas and/or plasma treatment, i.e. not by additional application via printing, the resulting structuring of the surface layer is an integral part of the surface layer and does not lie on the original surface, as would be the case with printing or bonding.

With the aid of the present invention, highly precise surface structures can be produced on size scales of nanometers to micrometers.

In preferred embodiments of the present invention, a cover, a protective material, or a mask is used whose recesses have a width of less than 1 mm, preferably between 1 μm and 0.5 mm, particularly preferably 50 μm to 500 μm or 300 μm to 500 μm. This allows preferred structures to be generated.

A detailed characterization of the surface structure can be carried out, for example, using profilometry (equipment for this is available, for example, under the brand name Dektak®) and/or microscopic methods. With the aid of scanning electron microscopy (SEM) and atomic force microscopy (AFM) surface structures, height profiles and mechanical properties can be determined in detail and compared with the specifications or simulations. These methods can provide necessary structural information on length scales from nanometers to micrometers, supplemented if desired by optical microscopy, which can provide structural information on scales down to millimeters.

By molding or imprinting the surface into other materials, the surface structure can also be transferred to a wide variety of other materials, depending on the requirements. For example, silicone surface structured by fold formation can serve as a base for transferring the surface structuring to polyurethane, epoxy resin or concrete. The structure then transfers—inverted—to the curing material, from whose surface the silicone can be easily removed. Microfluidic channel structures can also be integrated and used, for example, in a glass/elastomer sandwich structure in microfluidic chips.

With the help of the present invention, a wide variety of microstructured surfaces can be fabricated, such as self-cleaning surfaces, or microfluidic channel systems.

By the new structuring method of the present invention and in variants in combination with computer simulations the previously known folding methods are considerably augmented.

For the homogeneous layers used so far in the prior art, i.e., those that have been stretched and relaxed as a whole, without application or introduction of a pattern, the prediction of the fold pattern is quite straightforward. For the more complex of the structures of the present invention that can be produced with the present invention, computer simulations are used in preferred embodiments with which the structures formed can be predicted in-silico—and thus in a versatile and automated manner.

In these embodiments, it is possible to specify structural targets and with the aid of the simulations to calculate the associated inhomogeneity distributions. In this way, it is possible to create entirely novel structures relatively easily, such as overhangs, hierarchical folds, and channels.

Moreover, this method of the present invention is associated with automatic structure sharpening, the magnitude of which can be accurately determined: The resulting folded 3D structure is usually about one order of magnitude finer than the previously applied layer inhomogeneity. In addition, the method of the present invention has two further important advantages and unique features:
It allows the relatively simple fabrication of hierarchically structured surfaces—i.e., with small structures on larger structures on even larger structures, etc.—both uniaxially as well as biaxially.
It allows the creation of polarly aligned structures—i.e. with a predominant direction and not only a predominant axis. This can be of great importance e.g. for flow properties (stitch host “sharkskin”).

The simulation software used in preferred embodiments of the present invention is based on extensive preliminary work in the Human Brain Project on the folding of the human brain during embryonic development.

In the context of the present invention, the software is used in one embodiment in such a way that it calculates the corresponding target structure from a surface pattern. In the context of the present invention, in another embodiment, the software is used in such a way that it calculates from a desired target structure the surface pattern required for that. In this way, the present invention is of particular interest to the user since it enables the practical design of desired structures.

Consequently, the present invention relates, inter alia, to a manufacturing method using simulation software for ultra-precise surface patterning and thus for intelligent surface design.

In embodiments of the present invention, a “finite element simulation” is used to calculate which surface pattern results in which folding. Thereby, from a specified target structure, it is predicted which surface pattern results in folding results corresponding to the target structure. Since a direct inversion is difficult, a neural network is preferably used: Thus, in the simulations, the parameters of the folding are systematically examined and it is determined which distribution patterns (thickness and elasticity of the surface layer) result in which structures. In this embodiment, this pattern-structure data is reverse-learned into a neural network in order to subsequently determine suitable surface patterns with the help of the network. Thanks to the simulations, the network can test itself and improve further: The determined pattern is translated back into a 3D structure by means of the simulations, and thus serves as a new learning data set. This creates an in-silico cycle that continues to improve the predictions and expand the feasible structure space.

In one embodiment, this is finite element modeling under the following assumptions:
A hyperelastic (“neo-Hookean”) material, with a Poisson's ratio of 0.45, where the modulus of elasticity does not matter.
The substrate can be cross-linked in a controlled manner, as is possible, for example, with the aid of UV illumination or oxygen plasma (cf. above).
Due to the new crosslinking a new “present” form is assumed as the undeformed state, and the Young's modulus increases by a factor of 300.

The present invention can be used for many applications in which tailored surface structures are required. The market potential is correspondingly large. For example, microfluidic devices for use in medical diagnostics often fail because of cost, since the chips must be manufactured in expensive multistep lithography processes. In contrast, the present invention allows channel structures to be fabricated quickly and inexpensively in a single step. Similarly, with the present invention surfaces that are particularly easy to grip, or pleasant to the touch, for example for cell phones or dashboards of high-end vehicles can be created. Moreover, by creating surface structures similar to the lotus leaf, self-cleaning surfaces can be produced in a simple manner. Also, the modification of mechanical properties such as adhesion (e.g. gecko effect), as well as optical properties such as absorption and reflection, is also possible in a targeted manner through suitable structuring and material selection.

The advantageousness of the present invention also unfolds, for example, when the present invention is compared with prior art methods.

X-ray lithography can achieve structure sizes of >100 nm, with a throughput of square centimeters per hour. Suitable materials are organic photoresists and acrylates. The process can be used in microtechnology and is very expensive.

3D printing can achieve structure sizes of >50 μm, with a throughput of square centimeters per hour. Suitable materials are hydrogels, cells, and resins. The process can be used in medicine and microfluidics and is expensive.

Using laser ablation, structure sizes of >100 nm can be achieved, with a throughput of square millimeters per minute. Metals are suitable materials. The process can be used in electronics and medical technology and is expensive.

The comparison shows that the present invention expands manufacturing capabilities and complements existing processes. In some cases, the present invention is more cost-effective; in others, desired structures cannot be realized with other processes or can be realized only with considerable effort. One example for that are microfluidic channels with smooth, rounded cross-sections. These are hardly realizable with lithographic processes as they have been used up to now, but are readily realizable with the present invention.

With the method of the present invention, structure sizes of >100 nm can be achieved, in some cases at throughputs of up to square meters per second. As materials elastic materials such as silicones are (directly) suitable but also various others indirectly via molding. The method can be used wherever appropriate structures on surfaces are required and is inexpensive.

Surface structuring according to the present invention can be scaled up well and can in principle be carried out quickly and over large areas in continuous roll-to-roll processes, which allow throughputs of up to square meters per second, which is a great advantage from an economic point of view.

In the following, the invention is explained in more detail with reference to the figures. The figures are not necessarily to scale and are simplified. For example, common measures etc. familiar to those skilled in the art are not necessarily shown (screws, valves, reaction vessels, exact molecular structure, etc.) in order to facilitate the readability of the figures.

### FIGURE DESCRIPTION

FIG. 1 illustrates the fabrication of a workpiece using the method according to the invention. The photo-crosslinking of polymers and/or crosslinking via (oxygen) plasma treatment allows a controlled and local change of the surface hardness. To this end, FIG. 1 shows how an initially stretched (not shown here) material 1a,1b, for example a vinyl group-terminated polydimethylsiloxane (Sylgard® 184 PDMS-Kit) is selectively exposed or cured, in particular crosslinked, in different areas with the aid of a mask 2. In FIG. 1, this is shown by means of lightning symbols 5, which are intended to illustrate the UV radiation (or oxygen plasma or similar) (in the case of oxygen plasma, the mask 2 must be placed directly on the surface of the material, because otherwise it is cured equally everywhere). In this FIG. 1, the uncured material is indicated as filled area 1a, and the cured area of the material is indicated as shaded zone 1b. FIG. 1 also illustrates the influence of the distance of the mask from the surface of the material; because directly under the parts of the mask 2, the material in the upper part of FIG. 1 is also shown as hardened, but not to the same depth as in the areas not shielded by mask parts. This is because at a greater distance, the mask cannot fully shield the areas below it from UV radiation. The closer the mask is to the material, the sharper the boundary becomes, up to completely non-hardened areas under the areas shielded by the mask, as illustrated in the lower half of FIG. 1, where the mask 2 rests directly on the material (it is known to the person skilled in the art that the sharpness of the boundary also depends on which chemical reactions the hardening reaction is based on).

By the structure of the mask 2, illustrated here by bars of different widths, the influence of the UV radiation (or oxygen plasma, etc.) on certain areas of the surface is reduced and consequently a curing pattern/crosslinking pattern is created in the material.

The degree of hardening/crosslinking can be controlled by the duration and intensity of the radiation. The fold formation begins when the material relaxes to the unstretched state (not shown here.)

FIG. 2 illustrates in section a) a stretched polymer substrate with an unhardened zone 1a and a hardened and newly crosslinked, thus also stiffer, surface layer 1b (shaded). In the image shown, the cured layer 1b is slightly thinner in the central region. When the substrate relaxes (i.e., the stretching is cancelled), the stiffer, because hardened, layer folds, shown in sections b) and c). In this way, complex structures, such as channels in this case, can be created. Section d) illustrates how the structure can be transferred to other materials and inverted (here into sharp points) by molding with another material 3 (shown in check).

If no knowledge of the particular structure or the folding is yet available, the resulting structures can be predicted with modern computer simulations.

FIG. 3 exemplary shows the structure of a channel cross, which results when a cross-shaped weak point, i.e. a cross-shaped non-exposed or weakly exposed region is obtained in the stretched state. This folds upon relaxation to a cruciform channel structure. FIG. 3a shows a top view of the resulting cruciform channel structure, wherein the different lines represent contour lines, starting from the lowest point in the center of the figure. FIG. 3b shows a lateral section through the resulting structure just below the top of the 3.3 μm contour line of FIG. 3a. Here it can be clearly seen that the surface forms a channel, with the walls descending toward the center. The thick areas illustrate the hardened area, i.e. no hardening of the material took place in the center. FIG. 3c shows a three-dimensional representation of the cross-shaped channel structure shown in FIG. 3a, in which the line grid illustrates the deformations during relaxation.

FIG. 4 shows an example structure with dimples. Localized weak spots result in a regular dimple pattern, with the protrusions resulting from the weak spots defined during irradiation (or plasma treatment). FIG. 4a shows a top view of the resulting dimple structure, wherein the various lines represent contour lines, starting from the lowest point in the center of the figure. FIG. 4b shows a lateral section through the resulting structure at the level of the center of FIG. 4a. Here it can be seen that there is an unhardened area in the center. Towards the edges of FIG. 4, two nubs are indicated (partially shown). The thick areas illustrate the hardened area, i.e. no hardening of the material took place in the center. FIG. 4c shows a three-dimensional representation of the dimple structure shown in FIG. 4a, in which the line grid illustrates the deformations during relaxation.

FIG. 5 illustrates, in the form of a flowchart, a sequence for a machine-learning design as applicable to the present invention. A desired 3D structure is specified by the application or the user. It is illustrated how here a neural network then proposes a surface pattern that should fold into as similar a structure as possible. A simulation is then used to calculate how the pattern should fold at a given exposure. The result is passed to the neural network as a learning data set, and, if necessary (if this result does not match the 3D specification sufficiently), a new proposal is generated. Thus, an in-silico cycle (ISC) is created, in which new learning data sets for the neural network are constantly generated. Thus, each time the learning dataset of the neural network is extended, and the evolution of 3D structures is improved. The result pattern can then be checked or verified in the laboratory. From deviations between experiment and simulation, the parameters of the simulation can be improved.

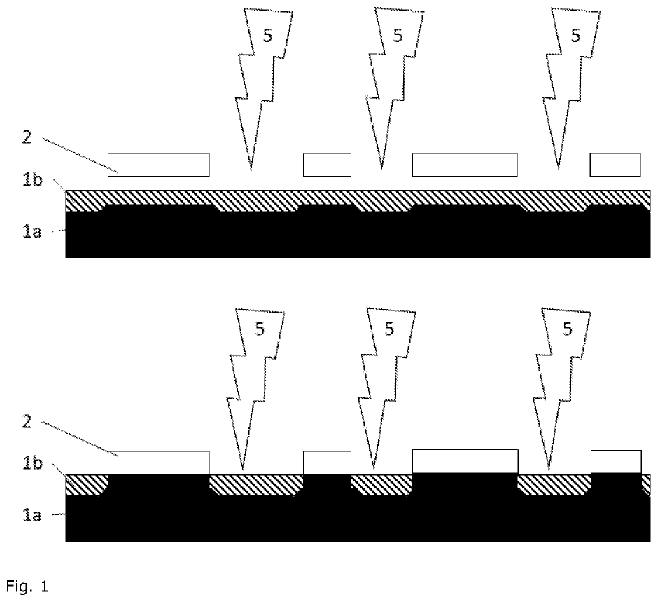

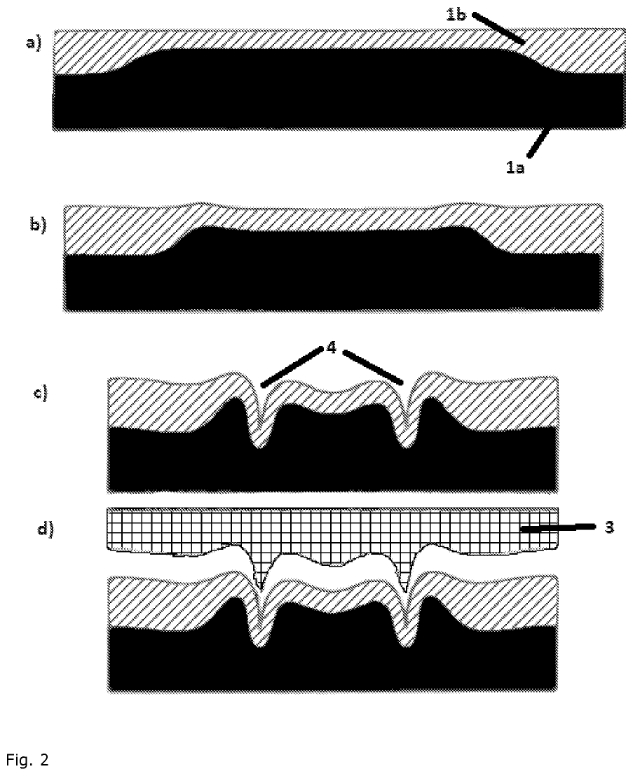

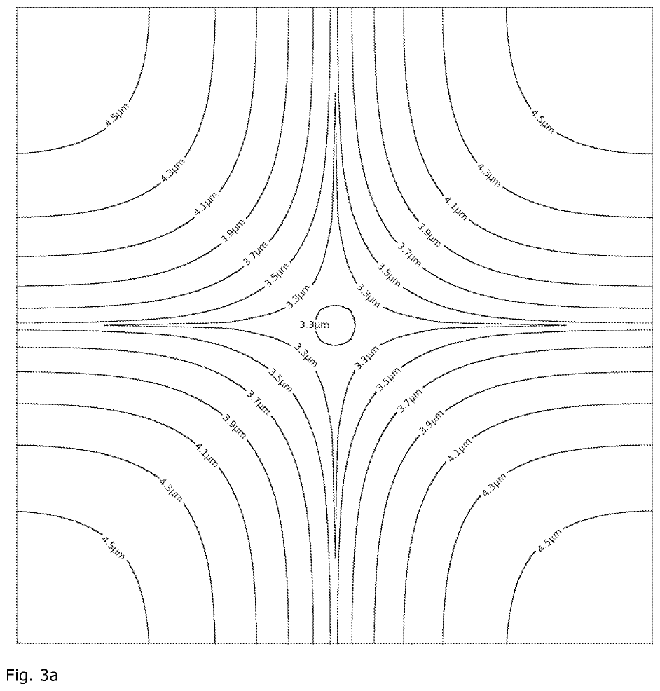

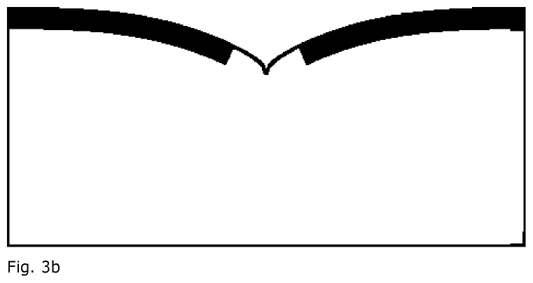

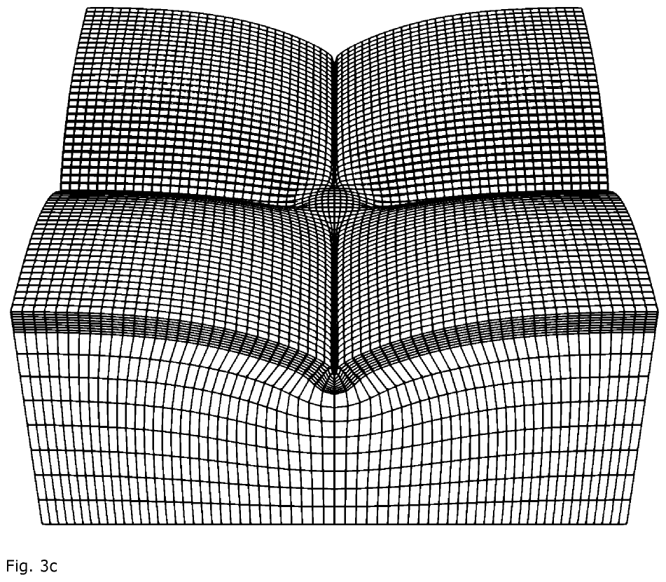

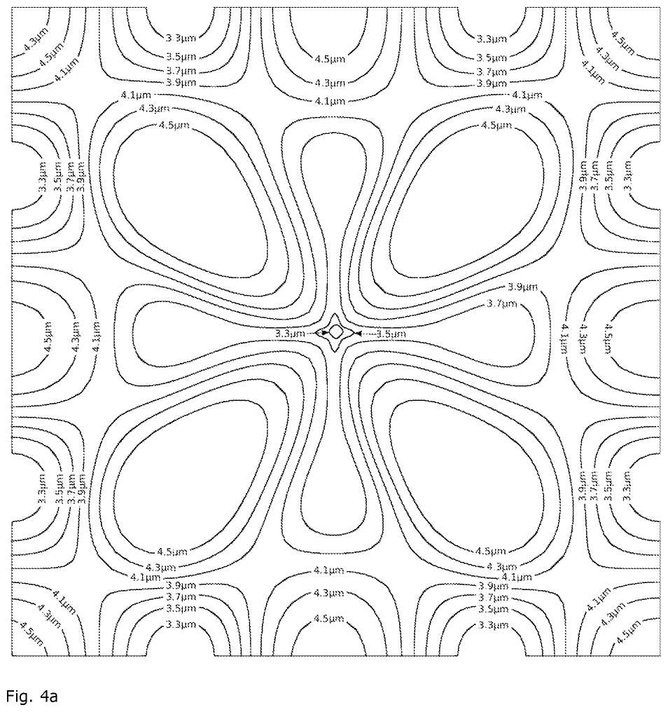

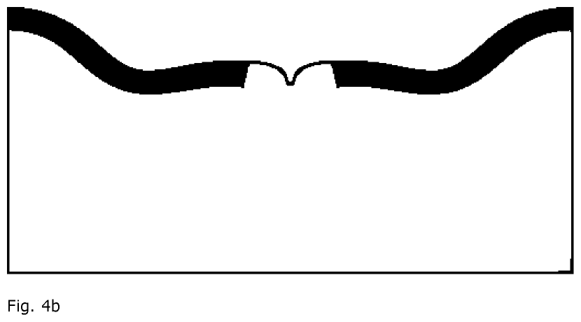

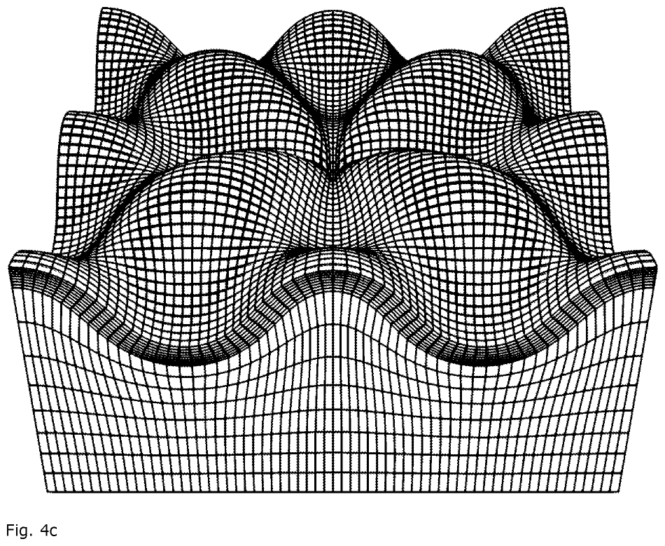

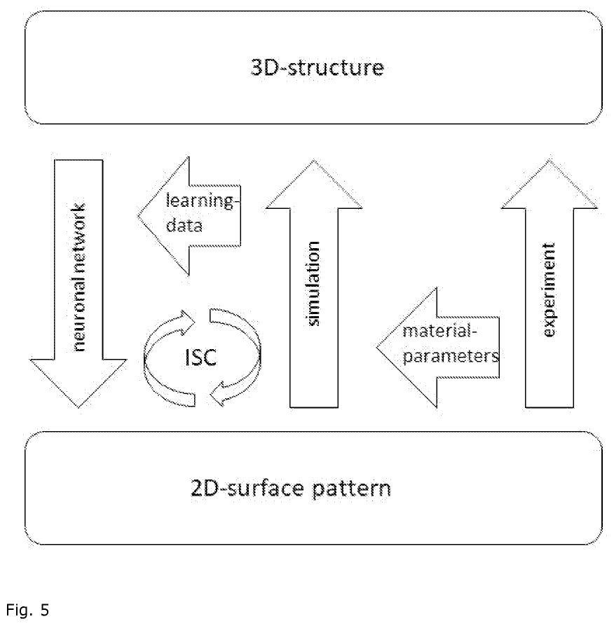

### LIST OF REFERENCE SIGNS

In the figures, the same reference signs mean the same materials, substances, etc.
1a elastic material, unhardened
1b elastic material, hardened
2 exposure mask
3 material for molding/molded material
4 (micro)channel
5 UV radiation (or oxygen plasma, etc.)

The present invention will now be explained in more detail with reference to the following non-limiting examples. The following non-limiting examples serve to set forth the embodiments embodied therein. It is known to the person skilled in the art that variations of these examples are possible within the scope of the present invention.

### EXAMPLES

### Example 1—Fabrication of a Channel Structure

A PDMS (Sylgard® 184) substrate block with an edge length of 4×4 cm and 3 mm thickness was stretched to 4.92 cm×4.92 cm. An aperture mask was placed on top, with square holes of 0.4 mm×0.4 mm. The web width was 0.1 mm.

The surface was then exposed to an oxygen plasma (100 W; 0.2 bar) for a duration of 10 minutes.

A workpiece was thus obtained consisting of a substrate block with a partially hardened but still stretched layer placed on its uppermost surface.

Thereafter, the stretching was cancelled and, upon relaxation to the unstretched state, the PDMS layer folded with shrinkage to its original size of 4×4 cm in a regular cross-shaped channel structure.

The resulting workpiece could be glued to a glass block.

### Example 2—Production of a Dimpled Pattern

Analogous to Example 1, a polydimethylsiloxane layer was stretched using an isotropic stretcher. Deviating from Example 1, however, it was stretched to 5.2 cm, and a round hole mask with hole diameter 1 mm and hole spacing 5 mm was used. Thus, the surface was hardened in the non-shaded area. The fold formation started when relaxing to the unstretched state and a regular dimple pattern was formed.

The dimple pattern thus obtained was transferred inversely by molding. For this purpose, the structure was filled with an epoxy resin and the epoxy resin was allowed to cure. Subsequently, the epoxy resin was lifted off the “dimple surface”.

Two complementary inverse textured surfaces were obtained.

1.-15. (canceled)

16. A method for producing three-dimensionally structured surfaces, wherein the method comprises or consists of:
a) providing an elastic material,
b) stretching the material by a predetermined value and maintaining a stretched state,
c) transferring a two-dimensional pattern to the elastic material in the stretched state or introducing a two-dimensional pattern into a surface of the elastic material in the stretched state,
d) cancelling the stretching, causing the material to fold itself corresponding to the transferred or introduced pattern,
e) optionally, molding of the patterned surface produced in d).

17. The method of claim 16, wherein the introduction of the two-dimensional pattern into the surface in c) is carried out as follows:
c1a) protecting specific surface areas of the elastic material by covering or applying a protective material,
c1b) allowing oxygen plasma or reactive gas to act on uncovered or unprotected surface areas,
c1c) removal of the covering or protective material,
or
c2a) placing an irradiation mask between a radiation source and the elastic material,
c2b) irradiation of the material in the stretched state with electromagnetic radiation for a specific duration and with a predetermined radiation intensity,
c2c) removal of the irradiation mask.

18. The method of claim 17, wherein the elastic material is an uppermost layer of a workpiece consisting of at least two different materials.

19. The method of claim 17, wherein the irradiation mask, a duration of irradiation, a radiation intensity and/or a degree of stretching are set depending on the elastic material used.

20. The method of claim 17, wherein the irradiation mask, a duration of irradiation, a radiation intensity and/or a degree of stretching are determined experimentally, experimentally iteratively and/or iteratively by machine learning and/or computer simulations.

21. The method of claim 20, wherein the experimentally iterative determination comprises or consists of:
i) specification of a desired three-dimensional surface structure for the defined elastic material,
iia) proposal of a two-dimensional surface pattern which, after irradiation through an irradiation mask, should fold into a structure as similar as possible to the specification, and
iib) proposing parameters for the duration of irradiation, the radiation intensity and/or the degree of stretching,
iii) carrying out a) to d) according to a method for producing three-dimensionally structured surfaces, which method comprises or consists of:
a) providing an elastic material,
b) stretching the material by a predetermined value and maintaining a stretched state,
c) transferring a two-dimensional pattern to the elastic material in the stretched state or introducing a two-dimensional pattern into a surface of the elastic material in the stretched state,
d) cancelling the stretching, causing the material to fold itself corresponding to the transferred or introduced pattern,
e) optionally, molding of the patterned surface produced in d).
iv) comparing the structure obtained in iii) with the specified structure,
v1) in case of sufficient match between the three-dimensional surface structure obtained in iii) and the specified surface structure, outputting the obtained product,
v1a) optionally storing the structure proposed in iia) and/or the parameters proposed in iib) and the corresponding obtained three-dimensional surface structure,
v2) in case of insufficient match between the three-dimensional surface structure obtained in iii) and the specified surface structure, repetition of ii) to iv) while changing the structure proposed in iia) and/or changing parameters proposed in iib) by an algorithm,
v2a) optionally storing the structure proposed in iia) and/or the parameters proposed in iib) and the corresponding obtained three-dimensional surface structure.

22. The method of claim 20, wherein the iterative determination is performed by means of machine learning and comprises or consists of:
I) specification of a desired three-dimensional surface structure for the defined elastic material,
IIa) proposal of a two-dimensional surface pattern, which after irradiation through an irradiation mask should fold into a structure as similar as possible to the specification, by an algorithm, and
IIb) proposal of parameters for the duration of irradiation, a radiation intensity and/or a degree of stretching by an algorithm,
IIa) calculating the folding of the surface pattern proposed in IIa) using the parameters proposed in IIb) by means of a simulation program,
IIIb) transfer of a calculation result as a learning data set to a neural network,
IV) comparing the structure calculated in III) with the specified structure,
V1) in case of sufficient match between the three-dimensional surface structure calculated in III) and the specified surface structure, outputting the surface structure proposed in IIa) and parameters proposed in IIb),
VIa) optionally storing the structure proposed in IIa) and/or the parameters proposed in IIb) and the corresponding obtained three-dimensional surface structure,
V2) in case of insufficient match between the three-dimensional surface structure obtained in III) and the specified surface structure, repetition of II) to IV) while changing the structure proposed in IIa) and/or changing the parameters proposed in IIb) by an algorithm,
V2a) optionally storing the structure proposed in IIa) and/or the parameters proposed in IIb) and the corresponding obtained three-dimensional surface structure.

23. The method of claim 17, wherein the desired surface structure, the irradiation mask, the duration of the irradiation, the radiation intensity and/or the degree of stretching are specified and, starting therefrom, it is determined
a) which material parameters an elastic material to be used must have, and/or
b) which elastic material can be used.

24. The method of claim 21, wherein the two-dimensional surface pattern proposed in iia) or IIa) corresponds to at least one defined exposure mask.

25. The method of claim 22, wherein the two-dimensional surface pattern proposed in iia) or IIa) corresponds to at least one defined exposure mask.

26. The method of claim 17, wherein a covering, a protective material, or a mask is used whose recesses have a width of less than 1 mm.

27. The method of claim 17, wherein a covering, a protective material, or a mask is used whose recesses have a width of from 1 μm to 0.5 mm.

28. The method of claim 17, wherein a covering, a protective material, or a mask is used whose recesses have a width of from 50 μm to 500 μm.

29. The method of claim 17, wherein a covering, a protective material, or a mask is used whose recesses have a width of from 300 μm to 500 μm.

30. The method of claim 16, wherein the resulting structured surface has hierarchical folds, overhangs, channels, microfluidic channels, dimples and/or combinations thereof.

31. A workpiece with a structured surface, produced with the method of claim 16.

32. The workpiece of claim 31, wherein the structured surface has hierarchical folds, overhangs and/or microfluidic channels with smooth, rounded cross-section.

33. The workpiece of claim 31, wherein the workpiece comprises at least two layers, the surface-structured surface being the uppermost layer.

34. A method for optimizing structured surfaces by means of machine learning, wherein the machine learning after specification of a desired three-dimensional surface structure comprises or consists of:
I) specification of a desired three-dimensional surface structure for an elastic material,
IIa) proposal by an algorithm of a two-dimensional surface pattern that should fold into a structure as similar as possible to the specification after irradiation through an irradiation mask, and
IIb) proposal of parameters for a duration of irradiation, a radiation intensity and/or a degree of stretching by an algorithm,
IIa) calculating a folding of the surface pattern proposed in IIa) using the parameters proposed in IIb) by means of a simulation program,
IIb) transfer of the calculation result as a learning data set to a neural network,
IV) comparing the structure calculated in III) with the specified structure,
V1) in case of sufficient match between the three-dimensional surface structure calculated in III) and the specified surface structure, outputting the surface structure proposed in IIa) and parameters proposed in IIb),
VIa) optionally storing the structure proposed in IIa) and/or the parameters proposed in IIb) and the corresponding obtained three-dimensional surface structure,
V2) in case of insufficient match between the three-dimensional surface structure obtained in III) and the specified surface structure, repetition of II) to IV) while changing the structure proposed in IIa) and/or changing the parameters proposed in IIb) by an algorithm,
V2a) optionally storing the structure proposed in IIa) and/or the parameters proposed in IIb) and the corresponding obtained three-dimensional surface structure.
